(19) United States
(12) Patent Application Publication
(10) Pub. No.: US 2008/0008843 A1
(43) Pub. Date: Jan. 10, 2008

(54) Method for Production of Metal Oxide Coatings

(76) Inventor: Fred Ratel, Tucson, AZ (US)

Correspondence Address: SHEPPARD MULLIN RICHTER & HAMPTON LLP, 48th Floor, 333 South Hope Street, Los Angeles, CA, 90071, US

(21) Appl. No.: 11/681,741

(22) Filed: Mar. 2, 2007

Related U.S. Application Data
(60) Provisional application No. 60/778,729, filed on Mar. 2, 2006.
(60) Provisional application No. 60/778,730, filed on Mar. 2, 2006.
(60) Provisional application No. 60/811,314, filed on Jun. 5, 2006.
(60) Provisional application No. 60/811,315, filed on Jun. 5, 2006.

(51) Int. Cl. C23C 16/06

(52) U.S. Cl. 427/576

(57) ABSTRACT

The present invention provides a method for forming metal oxide coatings on a substrate. The method includes the steps of: (a) subjecting a chamber containing a plasma source to vacuum; (b) feeding metal oxide precursor and O₂ into a chamber containing a plasma source, wherein the O₂ is fed into the chamber at a rate greater than that of the metal oxide precursor; (c) subjecting the substrate to the chamber, wherein the substrate is at a temperature less than 250° C., thereby forming a metal oxide coating on the substrate.

### CROSS-REFERENCE TO RELATED APPLICATIONS

This application claims priority to U.S. Provisional Patent Application Ser. No. 60/778,729 filed on Mar. 2, 2006, U.S. Provisional Patent Application Ser. No. 60/778,730 filed on Mar. 2, 2006, U.S. Provisional Patent Application Ser. No. 60/811,314 filed on Jun. 5, 2006 and U.S. Provisional Patent Application Ser. No. 60/811,315 filed on Jun. 5, 2006 the entire disclosures of which are incorporated by reference.

### FIELD OF THE INVENTION

The present invention provides a method for forming metal oxide coatings on a substrate.

### BACKGROUND OF THE INVENTION

Several techniques are known for depositing iron oxide coatings onto a substrate. Most of the methods, however, are limited in that substrate temperatures greater than 400° C. are used. This is because the oxides are pyrolytically formed on the substrate surface. Such procedures inherently limit the types of substrates that may be used, since substrates melting at high temperatures are prohibited.

It is accordingly an object of the present invention to provide a method of depositing iron oxide on a substrate at temperatures substantially below 400° C.

### SUMMARY OF THE INVENTION

The present invention provides a method for forming metal oxide coatings on a substrate. The method includes the steps of: (a) subjecting a chamber containing a plasma source to vacuum; (b) feeding a metal oxide precursor and O₂ into a chamber containing a plasma source, wherein the O₂ is fed into the chamber at a rate greater than that of the metal oxide precursor; (c) subjecting the substrate to the chamber, wherein the substrate is at a temperature less than 250° C., thereby forming a metal oxide coating on the substrate.

Metal Oxides

Metal oxides prepared by the method of the present invention include, but are not limited to, the following: tungsten oxide; doped tungsten oxide; titanium oxide; doped titanium oxide; zinc oxide; doped zinc oxide; tin oxide; doped tin oxide; indium oxide; doped indium oxide; doped iron oxide; and, any other combination of doped transition metal and/or post transition metal oxide arising from Columns IIIB to IVA of the Periodic Table, excluding undoped iron oxide.

Metal Oxide Coating

The surface of the metal oxide coatings typically exhibit individual structures (e.g., disc-like structures, box-like structures, diamond-like structures, etc.) that lie in a non-parallel orientation (e.g., vertical) with respect to the substrate plane. Such structures typically have a ratio of long dimension to short dimension of at least 2:1. Oftentimes the ratio is at least 3:1 or 4:1. In certain cases, the ratio is at least 5:1 or 6:1.

The metal oxide coatings typically contain at least 10 individual structures on their surface within a 0.25 μm² area. Oftentimes, the coatings contain at least 25 or 50 individual structures on their surface within a 0.25 μm² area.

Method of Deposition

Metal oxide precursor and O₂ are fed into a chamber, containing a plasma source, through two separate feed lines. The O₂ is fed in at a rate at least 4 times greater than that of the metal oxide precursor. The chamber is subjected to vacuum prior to deposition and maintained under vacuum throughout the procedure. A substrate is subjected to the chamber, resulting in the production of a metal oxide coating on the substrate. During the deposition, the substrate is at a temperature less than 250° C.

The plasma source is typically a high density plasma source, and it is oftentimes an argon plasma source. In certain cases, O₂ is fed into the chamber at a rate at least 8 times greater than that of the metal oxide precursor, and oftentimes it is fed at a rate at least 12 times greater. The chamber is typically subjected to a vacuum of at least 0.10 torr, and, in some cases, to a vacuum of at least 0.01 torr or even 0.005 torr. Substrates may be of any suitable composition. Nonlimiting examples include a spectrally transparent cyclic-olefin copolymer, pure poly(norbornene), and a conducting glass plate having an F-doped SnO₂ overlayer. The substrate temperature during the deposition is usually less than 200° C. In certain cases it may be less than 175° C., 150° C., or 125° C.

Substrates are usually passed through the chamber during the coating process at a rate of at least 1 mm/s. Oftentimes, the substrates are passed through at a rate of at least 3 mm/s, 5 mm/s, or even 7 mm/s. Coating thicknesses on the substrate usually exceed 500 Å, and can exceed 750 Å or even 1000 Å.

Nonlimiting examples of metal oxide precursors include pyrophoric organometallic precursors such as iron pentacarbonyl, diethylzinc, and dibutyltin diacetate. Other gaseous and/or liquid metal-containing precursors with a vapor pressure higher than water (e.g., tungsten hexafluoride) may also be used.

The following are non-limiting examples of the method of the present invention:

1. Plasma Source: High density.
O₂ Feed Rate: At least 50 sccm.
Metal Oxide Precursor Feed Rate: At least 10 sccm.
Chamber Pressure: Less than 0.1 torr.
Substrate Composition: Spectrally transparent cyclic-olefin polymer.
Substrate Temperature: Less than 250° C.
Metal Oxide Form: At least 10 individual structures on the surface within a 0.25 μm² area.
Metal Oxide Coating Thickness: Greater than 500 Å.

2. Plasma Source: High density.
O₂ Feed Rate: At least 75 sccm.
Metal Oxide Precursor Feed Rate: At least 15 sccm.
Chamber Pressure: Less than 0.1 torr.
Substrate Composition: Spectrally transparent cyclic-olefin polymer.
Substrate Temperature: Less than 250° C.
Metal Oxide Form: At least 10 individual structures on the surface within a 0.25 μm² area.
Metal Oxide Coating Thickness: Greater than 500 Å.

3. Plasma Source: High density.
O₂ Feed Rate: At least 75 sccm.
Metal Oxide Precursor Feed Rate: At least 15 sccm.
Chamber Pressure: Less than 0.1 torr.
Substrate Composition: Spectrally transparent cyclic-olefin polymer.
Substrate Temperature: Less than 200° C.
Metal Oxide Form: At least 10 individual structures on the surface within a 0.25 μm² area.
Metal Oxide Coating Thickness: Greater than 500 Å.

4. Plasma Source: High density.
O₂ Feed Rate: At least 75 sccm.
Metal Oxide Precursor Feed Rate: At least 15 sccm.
Chamber Pressure: Less than 0.1 torr.
Substrate Composition: Spectrally transparent cyclic-olefin polymer.
Substrate Temperature: Less than 175° C.
Metal Oxide Form: At least 10 individual structures on the surface within a 0.25 μm² area.
Metal Oxide Coating Thickness: Greater than 500 Å.

5. Plasma Source: High density argon.
O₂ Feed Rate: At least 100 sccm.
Metal Oxide Precursor Feed Rate: At least 15 sccm.
Chamber Pressure: Less than 0.01 torr.
Substrate Composition: Spectrally transparent cyclic-olefin polymer.
Substrate Temperature: Less than 175° C.
Metal Oxide Form: At least 25 individual structures on the surface within a 0.25 μm² area.
Metal Oxide Coating Thickness: Greater than 500 Å.
Substrate Pass-Through Rate: At least 3 mm/s.

6. Plasma Source: High density argon.
O₂ Feed Rate: At least 150 sccm.
Metal Oxide Precursor Feed Rate: At least 15 sccm.
Chamber Pressure: Less than 0.01 torr.
Substrate Composition: Spectrally transparent cyclic-olefin polymer.
Substrate Temperature: Less than 150° C.
Metal Oxide Form: At least 25 individual structures on the surface within a 0.25 μm² area.
Metal Oxide Coating Thickness: Greater than 750 Å.
Substrate Pass-Through Rate: At least 3 mm/s.

7. Plasma Source: High density argon.
O₂ Feed Rate: At least 150 sccm.
Metal Oxide Precursor Feed Rate: At least 15 sccm.
Chamber Pressure: Less than 0.01 torr.
Substrate Composition: Spectrally transparent cyclic-olefin polymer.
Substrate Temperature: Less than 150° C.
Metal Oxide Form: At least 10 individual structures on the surface within a 0.25 μm² area.
Metal Oxide Coating Thickness: Greater than 1000 Å.
Substrate Pass-Through Rate: At least 3 mm/s.

8. Plasma Source: High density argon.
O₂ Feed Rate: At least 150 sccm.
Metal Oxide Precursor Feed Rate: At least 15 sccm.
Chamber Pressure: Less than 0.01 torr.
Substrate Composition: Spectrally transparent cyclic-olefin polymer.
Substrate Temperature: Less than 150° C.
Metal Oxide Form: At least 10 individual structures on the surface within a 0.25 μm² area.
Metal Oxide Coating Thickness: Greater than 1000 Å.
Substrate Pass-Through Rate: At least 5 mm/s.

9. Plasma Source: High density argon.
O₂ Feed Rate: At least 150 sccm.
Metal Oxide Precursor Feed Rate: At least 15 sccm.
Chamber Pressure: Less than 0.01 torr.
Substrate Composition: Poly(norbornene).
Substrate Temperature: Less than 150° C.
Metal Oxide Form: At least 10 individual structures on the surface within a 0.25 μm² area.
Metal Oxide Coating Thickness: Greater than 1000 Å.
Substrate Pass-Through Rate: At least 5 mm/s.

10. Plasma Source: High density argon.
O₂ Feed Rate: At least 150 sccm.
Metal Oxide Precursor Feed Rate: At least 15 sccm.
Chamber Pressure: Less than 0.01 torr.
Substrate Composition: Conducting glass plate having an F-doped SnO₂ overlayer
Substrate Temperature: Less than 150° C.
Metal Oxide Form: At least 10 individual structures on the surface within a 0.25 μm² area.
Metal Oxide Coating Thickness: Greater than 1000 Å.
Substrate Pass-Through Rate: At least 5 mm/s.

### EXAMPLE

### Example 1

Deposition of Metal Oxide on Cyclic Olefin Copolymer

A sheet of Topas cyclic olefin copolymer is coated with metal oxide in the following manner. Metal oxide precursor and O₂ are fed into a chamber, containing a high density argon plasma source operating at 3000 W (Sencera, Charlotte, N.C.), at a rate of 20 sccm and 240 sccm respectively through two separate feed lines. The chamber is pumped down to 0.005 Torr prior to deposition and maintained at that pressure throughout the process. The sheet, which is at a temperature of 140° C., is passed over the feed outlets on a moving carriage at a speed of 5 mm/s to achieve a metal oxide deposit thickness of 1500 Å.

1. A method of forming a metal oxide coating on a substrate, wherein the method comprises the following steps:
(a) subjecting a chamber containing a plasma source to vacuum;
(b) feeding a metal oxide precursor and O₂ into a chamber containing a plasma source, wherein the O₂ is fed into the chamber at a rate at least 4 times greater than that of the metal oxide precursor;
(c) subjecting the substrate to the chamber, wherein the substrate is at a temperature less than 250° C.
thereby forming a metal oxide coating on the substrate, wherein the coating is greater than 500 Å thick.

2. The method according to claim 1, wherein the metal oxide precursor is fed into the chamber at a rate of at least 10 sccm.

3. The method according to claim 1, wherein the plasma source is a high density argon plasma source.

4. The method according to claim 1, wherein the substrate comprises a spectrally transparent cyclic olefin polymer.

5. The method according to claim 1, wherein the substrate is at a temperature less than 200° C.

6. The method according to claim 1, wherein the coating on the substrate is greater than 750 Å thick.

7. The method according to claim 1, wherein the metal oxide coating has at least 10 individual structures on its surface within a 0.25 μm² area.

8. The method according to claim 1, wherein the O₂ is fed into the chamber at a rate at least 8 times greater than that of the metal oxide precursor.

9. The method according to claim 8, wherein the plasma source is a high density argon plasma source.

10. The method according to claim 9, wherein the substrate is at a temperature less than 175° C.
